(19) United States
(12) Patent Application Publication
(10) Pub. No.: US 2013/0026516 A1
(43) Pub. Date: Jan. 31, 2013

(54) LIGHT-EMITTING DIODE (LED) PACKAGE STRUCTURE AND PACKAGING METHOD THEREOF

(71) Applicants: Jih-Fu Wang, Taichung (TW); Chien-Ping Huang, Taichung (TW); Wen-Hao Lee, Taichung (TW); Hsien-Wen Chen, Taichung (TW); Ming-Hsiu Lee, Taichung (TW)

(72) Inventors: Jih-Fu Wang, Taichung (TW); Chien-Ping Huang, Taichung (TW); Wen-Hao Lee, Taichung (TW); Hsien-Wen Chen, Taichung (TW); Ming-Hsiu Lee, Taichung (TW)

(73) Assignee: SILICONWARE PRECISION INDUSTRIES CO., LTD., Taichung (TW)

(21) Appl. No.: 13/223,479

(22) Filed: Sep. 1, 2011

(30) Foreign Application Priority Data
Jul. 29, 2011 (TW) 100126953

(51) Int. Cl. H01L 33/60

(52) U.S. Cl. 257/98; 438/27; 257/E33.06

(57) ABSTRACT

A light-emitting diode (LED) package structure and a packaging method thereof are provided. The packaging method includes: forming first conductive layers on a silicon substrate, and forming a reflection cavity and electrode via holes from a top surface of the silicon substrate; forming a reflection layer on predetermined areas of a surface of the reflection cavity, and forming second conductive layers and metal layers on surfaces of the electrode via holes; and mounting a chip and forming an encapsulant, so as to fabricate the LED package structure. In the present invention, there is no need to perform at least two plating processes for connecting upper and lower conductive layers of the silicon substrate in the electrode via holes, and the problem of poor connection of the conductive layers in the electrode via holes can be avoided, thereby making the fabrication processes simplified and time-effective and also improving the overall production yield.

### BACKGROUND OF THE INVENTION

1. Field of the Invention

The present invention relates to package structures and packaging methods thereof, and more particularly, to a light-emitting diode (LED) package structure and a packaging method thereof.

2. Description of Related Art

Applying semiconductor fabrication processes to silicon (Si) wafer advantageously allows massive production of LED submounts, and also favors cost reduction and yield increase for package manufacturers as well as provides packages with better heat dissipating performance.

Taiwanese Patent No. I331415 has disclosed an LED packaging technique in the use of the semiconductor fabrication processes. According to the specification and drawings of this patent, a silicon substrate covered with insulating layers thereon is provided, and conductive layers and electrodes connected thereto are formed on upper and lower surfaces of the silicon substrate and in electrode via holes of the silicon substrate. Then, a chip is mounted on the conductive layer formed on the upper surface of the silicon substrate, and wire-bonding and encapsulating processes are subsequently performed.

However, the above patent's technique requires the conductive layers and the electrodes to be formed on the upper and lower surfaces of the silicon substrate and to be electrically connected to each other in the electrode via holes of the silicon substrate. This must use the relatively complicated sputter process to form the conductive layers, thereby making the packaging technique time-ineffective and cost-ineffective. Further, it is found that the electrical connection between the conductive layers and the electrodes in the electrode via holes of the silicon substrate is not good enough when actually carrying out the above patent's technique. That is, it is not easy for the conductive layers and the electrodes to be completely electrically connected to each other in the electrode via holes of the silicon substrate. This directly impairs the light emitting effect of the chip and adversely affects the production yields. Moreover, during the encapsulating process to form a molding compound for filling the electrode via holes of the silicon substrate, a mold flash problem easily arises.

Therefore, how to overcome the above drawbacks of the conventional technology is becoming one of the most popular issues in the art.

### SUMMARY OF THE INVENTION

In view of the drawbacks of the prior art, the present invention provides a light-emitting diode (LED) package structure, comprising: a silicon substrate including a first surface, a second surface opposing to the first surface, a reflection cavity formed in the silicon substrate and communicating with the first surface, and a plurality of electrode via holes formed through a bottom surface of the reflection cavity and the second surface; first conductive layers formed on the second surface of the silicon substrate; first insulating layers formed on the first surface of the silicon substrate, a surface of the reflection cavity and surfaces of the electrode via holes; a reflection layer formed on the first insulating layers located on predetermined areas of the surface of the reflection cavity; second conductive layers formed on the surfaces of the electrode via holes and connected to the first conductive layers; metal layers formed on the second conductive layers; a chip mounted in the reflection cavity and electrically connected to the metal layers; and an encapsulant formed in the reflection cavity and the electrode via holes, and covering the first insulating layers, the reflection layer, the metal layers and the chip.

In order to fabricate the LED package structure, the present invention also provides a packaging method of the LED package structure, comprising the steps of: providing a silicon substrate having a first surface and a second surface opposing to the first surface, and forming first conductive layers on the second surface of the silicon substrate; forming a reflection cavity from the first surface into the silicon substrate, and forming a plurality of electrode via holes penetrating through a bottom surface of the reflection cavity and the second surface of the silicon substrate; forming first insulating layers on the first surface of the silicon substrate, a surface of the reflection cavity and surfaces of the electrode via holes; forming a reflection layer on the first insulating layers located on predetermined areas of the surface of the reflection cavity; forming second conductive layers on the surfaces of the electrode via holes, wherein the second conductive layers are connected to the first conductive layers; forming metal layers on the second conductive layers; mounting a chip in the reflection cavity, and electrically connecting the chip to the metal layers; and forming an encapsulant in the reflection cavity and the electrode via holes, allowing the encapsulant to cover the first insulating layers, the reflection layer, the metal layers and the chip.

Compared to the conventional technology, the present invention does not need to perform at least two plating processes for connecting upper and lower conductive layers of the silicon substrate in the electrode via holes, and the problem of poor connection of the conductive layers in the electrode via holes can be avoided, thereby making the fabrication processes simplified and time-effective and also improving the overall production yield. Moreover, the present invention allows the electrode via holes to be covered by the first conductive layers, such that a mold flash problem does not occur during the subsequent process of forming the encapsulant.

### BRIEF DESCRIPTION OF DRAWINGS

The present invention can be more fully understood by reading the following detailed description of the preferred embodiments, with reference made to the accompanying drawings, wherein:

FIGS. 1A to 1T are schematic diagrams illustrating an LED package structure and a packaging method thereof according to the present invention, wherein FIG. 1K′ is a top view of FIG. 1K, and FIG. 1T′ is a schematic diagram showing a flip chip provided in a reflection cavity.

### DETAILED DESCRIPTION OF PREFERRED EMBODIMENTS

The following illustrative embodiments are provided to illustrate the disclosure of the present invention; those in the art can apparently understand these and other advantages and effects after reading the disclosure of this specification. The present invention can also be performed or applied by other different embodiments. Some terms such as “first”, “second” and “bottom surface” used in the specification are only for easy illustration but not for limiting the scope of the present invention. The details of the specification may be on the basis of different points and applications, and numerous modifications and variations can be devised without departing from the spirit of the present invention.

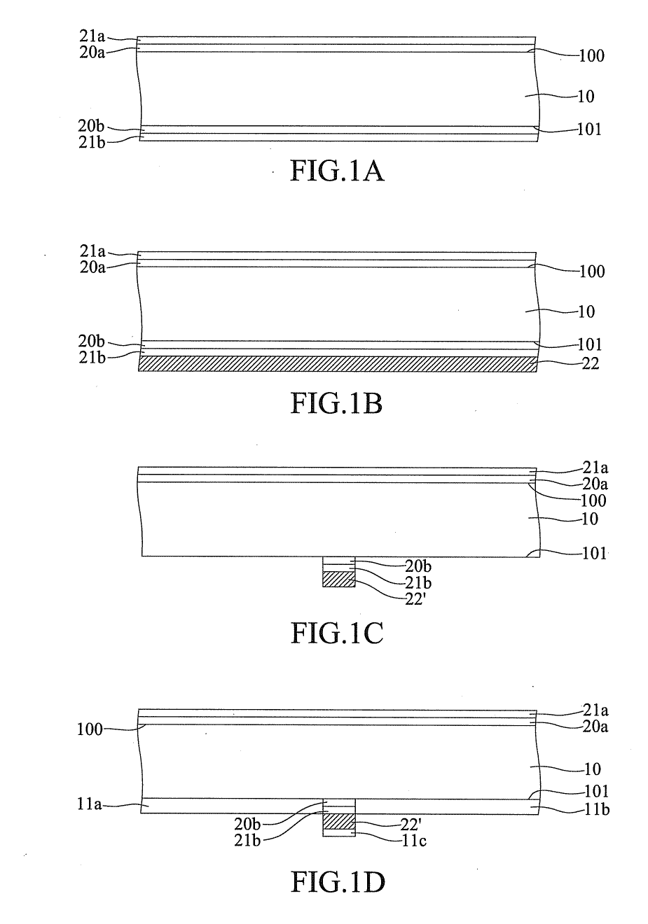

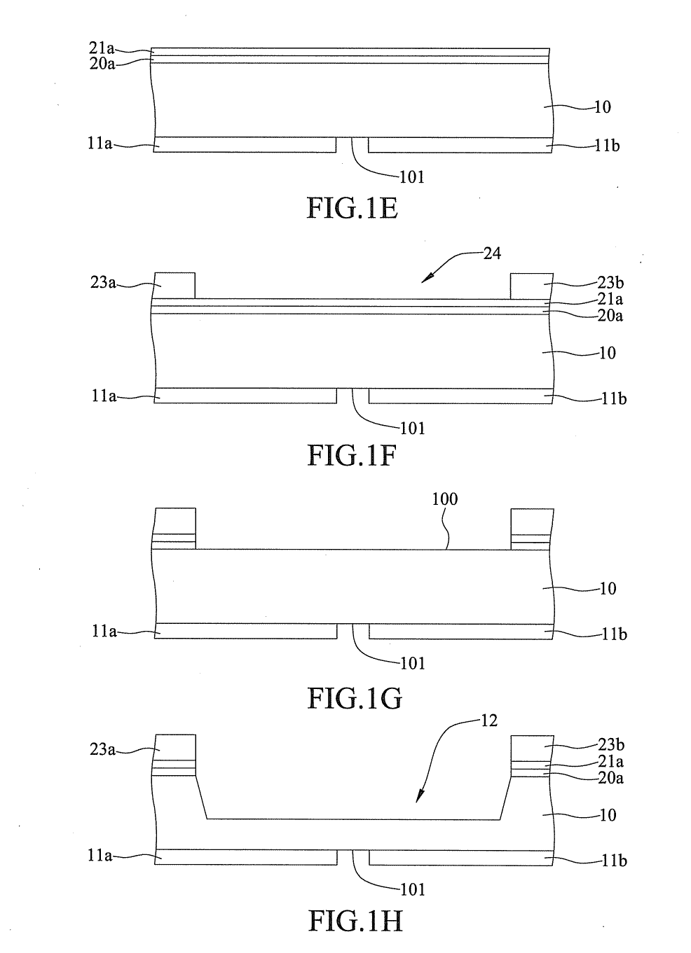

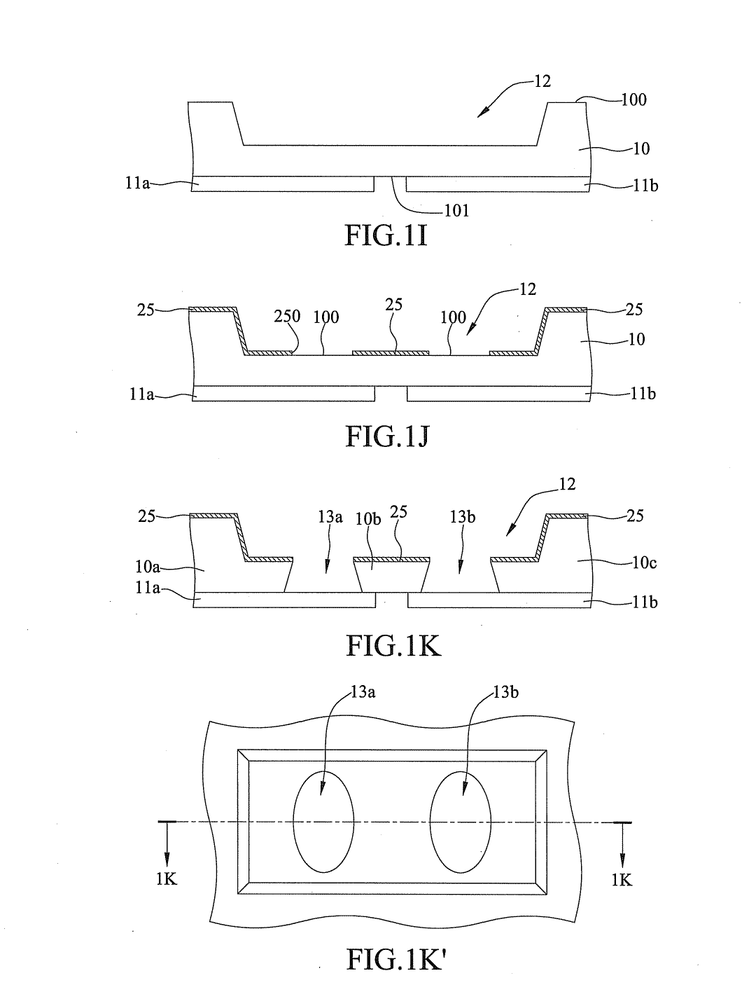

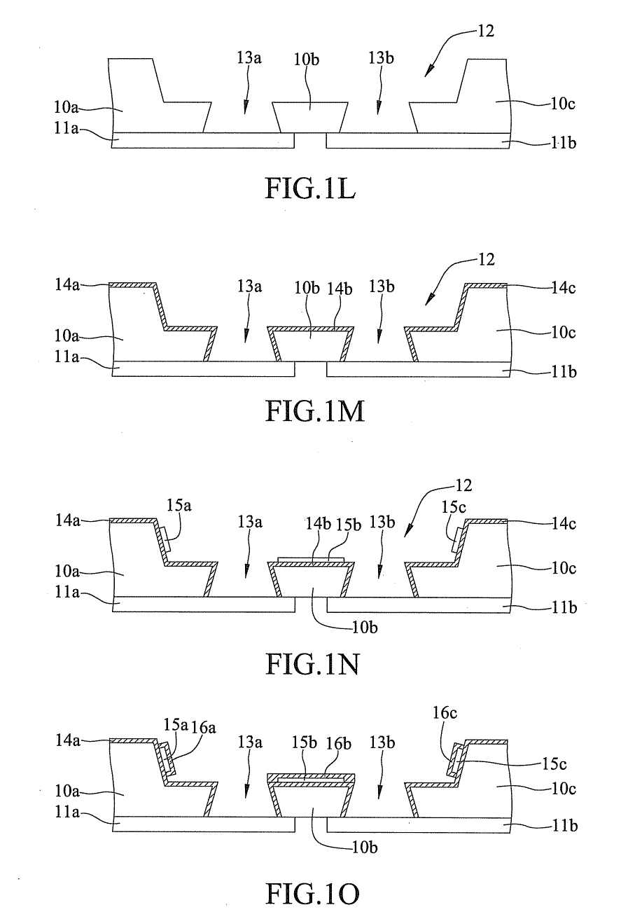

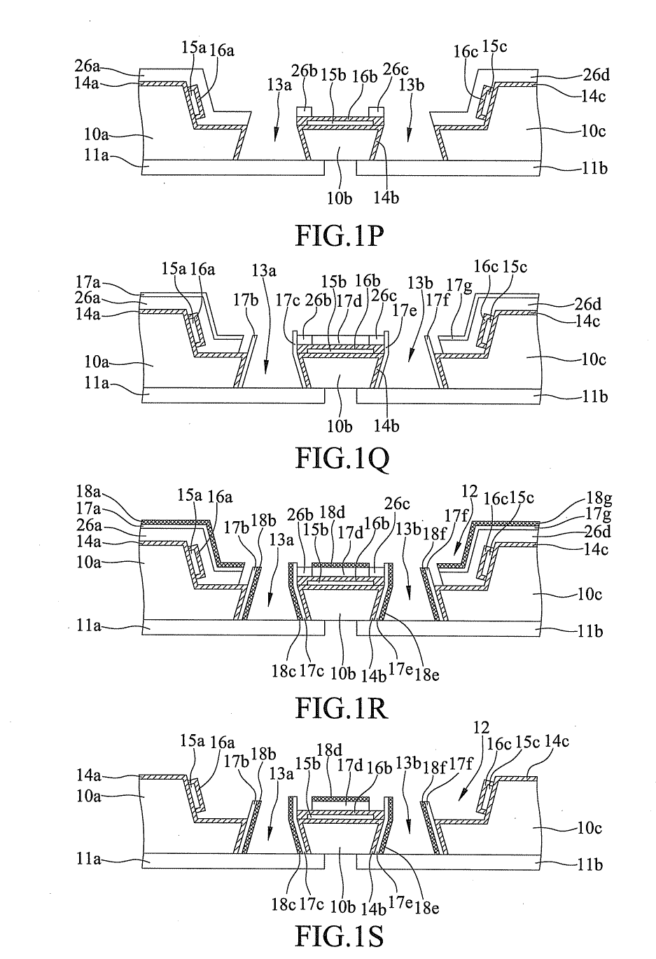

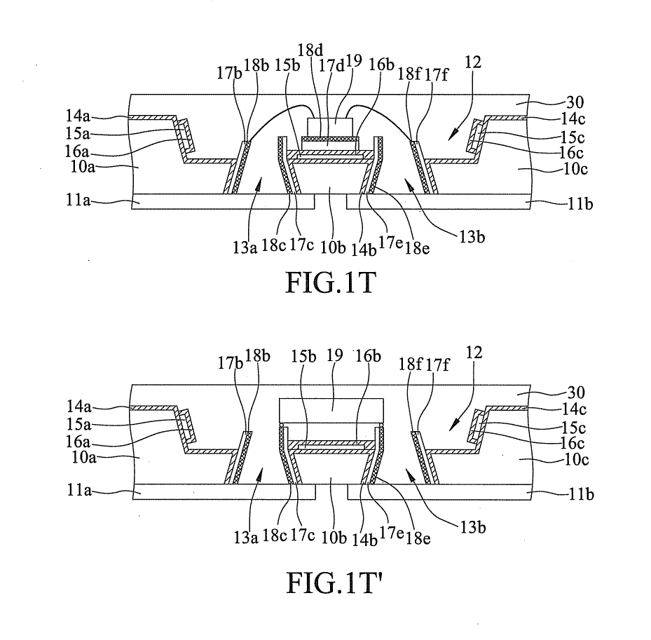

FIGS. 1A to 1T illustrate a light-emitting diode (LED) package structure and a packaging method thereof according to the present invention.

Referring to FIGS. 1A to 1E, firstly, a silicon substrate 10 having a first surface 100 and a second surface 101 opposing to the first surface 100 is provided. First conductive layers 11a, 11b are formed on the second surface 101 of the silicon substrate 10.

More specifically, as shown in FIG. 1A, a dielectric layer 20a (such as SiO₂) and another dielectric layer 21a (such as SiNx) can be sequentially formed on the first surface 100 of the silicon substrate 10. Similarly, a dielectric layer 20b (such as SiO₂) and another dielectric layer 21b (such as SiNx) can also be sequentially formed on the second surface 101 of the silicon substrate 10. It should be understood that there may only be formed one dielectric layer on either surface of the silicon substrate 10 depending on the requirements.

As shown in FIGS. 1B and 1C, a dry film 22 is applied on the dielectric layers 20b, 21b on the second surface 101 of the silicon substrate 10 and is subjected to a patterning process so as to form a patterned dry film 22′. Then, portions of the dielectric layers 20b, 21b, which are not covered by the patterned dry film 22′, are removed to partly expose the second surface 101 of the silicon substrate 10.

As shown in FIG. 1D, the first conductive layers 11a, 11b are deposited on the exposed parts of the second surface 101 of the silicon substrate 10. Further, another first conductive layer 11c can be deposited on the patterned dry film 22′ that is located on a central area of the second surface 101 of the silicon substrate 10.

As shown in FIG. 1E, the patterned dry film 22′ and the dielectric layers 20b, 21b covered thereby are removed, that is, the first conductive layer 11c, the patterned dry film 22′ and the dielectric layers 20b, 21b remaining on the central area of the second surface 101 of the silicon substrate 10 are stripped, such that a portion (or the central area) of the second surface 101 of the silicon substrate 10 can be exposed between the first conductive layers 11a, 11b.

Referring to FIGS. 1F to 1L, after forming the first conductive layers 11a, 11b, a reflection cavity 12 is provided on the first surface 100 of the silicon substrate 10, and a plurality of electrode via holes 13a, 13b are formed through the first and second surfaces 100, 101 of the silicon substrate 10.

More specifically, as shown in FIG. 1F, patterned photo resist layers 23a, 23b are formed on the first surface 100 of the silicon substrate 10 and have an opening 24 therebetween, wherein the opening 24 exposes a portion of the dielectric layer 21a. The exposed portion of dielectric layer 21a has a projection area beyond an area of the portion of the second surface 101 exposed from the first conductive layers 11a, 11b. Then, the portions of the dielectric layers 20a, 21a exposed from the opening 24 are removed by e.g. etching, such that a portion of the first surface 100 of the silicon substrate 10 is exposed, as shown in FIG. 1G.

As shown in FIG. 1H, the patterned photo resist layers 23a, 23b further serve as a mask, and etching is performed to form the reflection cavity 12 (such as a trapezoid cavity) into the silicon substrate 10, wherein the reflection cavity 12 communicates with the first surface 100 of the silicon substrate 10.

As shown in FIG. 1I, after forming the reflection cavity 12, the patterned photo resist layers 23a, 23b are removed, and the dielectric layers 20a, 21a covered by the patterned photo resist layers 23a, 23b are also removed. With those layers being removed, a first resist layer 25 (such as parylene) can be applied on the first surface 100 of the silicon substrate 10 and a surface of the reflection cavity 12, and then is subjected to patterning (e.g. by laser) to form first resist openings 250 by which portions of a bottom surface of the reflection cavity 12 are exposed, as shown in FIG. 1J.

After forming the first resist layer 25, reactive-ion etching (RIE) can be performed on the exposed portions of the bottom surface of the reflection cavity 12 to form the plurality of electrode via holes 13a, 13b penetrating through the bottom surface of the reflection cavity 12 and the second surface 101 of the silicon substrate 10, thereby exposing portions of the first conductive layers 11a, 11b, as shown in FIG 1K. Further as shown in the top view of FIG. 1K′, the electrode via holes 13a, 13b can have an oval shape or any other shape such as rectangle. According to the cross-section line 1K-1K of FIG. 1K′, the silicon substrate 10 can be divided into sections 10a, 10b, 10c, as shown in FIG. 1K.

After forming the electrode via holes 13a, 13b, the first resist layer 25 can be removed, as shown in FIG. 1L.

As shown in FIG. 1M, after removing the first resist layer 25, first insulating layers 14a, 14b, 14c are formed on the first surface 100 of the silicon substrate 10, in the reflection cavity 12 and on walls of the electrode via holes 13a, 13b. The first insulating layers 14a, 14b, 14c can have their bottom portions being in contact with the first conductive layers 11a, 11b.

Further as shown in FIG. 1M, the first insulating layers 14a, 14b, 14c can be applied respectively on the silicon substrate sections 10a, 10b, 10c. More specifically, the first insulating layer 14a is connected to the first conductive layer 11a by the wall of the electrode via hole 13a. The first insulating layer 14b is connected to the first conductive layers 11a, 11b by the walls of the electrode via holes 13a, 13b. The first insulating layer 14c is connected to the first conductive layer 11b by the wall of the electrode via hole 13b. And, the first insulating layers 14a, 14b, 14c can be made of SiO₂.

Referring to FIGS. 1N to 1O, with the first insulating layers 14a, 14b, 14c being provided, a reflection layer is formed on the first insulating layers 14a, 14b, 14c and on walls of the reflection cavity 12. The reflection layer can comprise metal films and second insulating layers.

As shown in FIG. 1N, metal films 15a, 15b, 15c (such as aluminum) are coated on the first insulating layers 14a, 14b, 14c. More specifically, the metal films 15a, 15c are located on the walls of the reflection cavity 12, and the metal film 15b is located on a central area of the bottom surface of the reflection cavity 12.

As shown in FIG. 10, second insulating layers 16a, 16b, 16c (made of such as SiO₂) are formed on the metal films 15a, 15b, 15c, and are respectively connected to the first insulating layers 14a, 14b, 14c so as to completely cover the metal films 15a, 15b, 15c. It should be understood that, depending on practical requirements, the metal film 15b and the second insulating layer 16b located on the bottom surface of the reflection cavity 12 may not be formed.

Referring to FIGS. 1P to 1Q, after forming the second insulating layers 16a, 16b, 16c, second conductive layers are formed on the first insulating layers 14a, 14b, 14c or the second insulating layers 16a, 16b, 16c, and can be connected to the first conductive layers by the electrode via holes.

As shown in FIG. 1P, second resist layers 26a, 26b, 26c, 26d (such as parylene) are applied on the first or second insulating layers. More specifically, the second resist layer 26a covers the first insulating layer 14a and the second insulating layer 16a. The second resist layer 26d covers the first insulating layer 14c and the second insulating layer 16c. The second resist layers 26b, 26c are located on peripheral areas of the second insulating layer 16b, with a central area of the second insulating layer 16b being exposed.

As shown in FIG. 1Q, after the second resist layers 26a, 26b, 26c, 26d are applied, a second conductive material is formed to cover the second resist layers 26a, 26b, 26c, 26d and the walls of the electrode via holes 13a, 13b. Then, a laser drilling process is performed to remove portions of the second resist layers 26a, 26d on peripheral areas of the electrode via holes 13a, 13b and remove the second conductive material on those portions of the second resist layers 26a, 26d, so as to form second conductive layers 17a, 17b, 17c, 17d, 17e, 17f, 17g.

The second conductive layers 17a, 17b are formed by laser drilling that also removes portions of the second resist layers 26a, 26d, such that a gap is left between the second conductive layers 17a, 17b, and a portion of the first insulating layer 14a is exposed through the gap. Similarly, a portion of the second resist layer 26b is exposed through a gap between second conductive layers 17c, 17d. A portion of the second resist layer 26c is exposed through a gap between second conductive layers 17d, 17e. And, a portion of the first insulating layer 14c is exposed through a gap between the second conductive layers 17f, 17g.

It should be understood that, the second conductive layers 17b, 17c and the second conductive layers 17e, 17f can be connected to the first conductive layer 11a and the first conductive layer 11b respectively by the electrode via hole 13a and the electrode via hole 13b. Moreover, the second conductive layers 17b, 17c and the second conductive layers 17e, 17f can be protruded upwardly on the bottom surface of the reflection cavity 12 from the first conductive layers 11a, 11b.

Referring to FIG. 1R to 1S, with the second conductive layers 17a, 17b, 17c, 17d, 17e, 17f, 17g being provided, metal layers are further formed on the second conductive layers 17b, 17c, 17e, 17f that are connected to the first conductive layers 11a, 11b by the electrode via holes 13a, 13b.

As shown in FIG. 1R, an electroplating process is performed to form metal layers 18a, 18b, 18c, 18d, 18e, 18f, 18g on the second conductive layers 17a, 17b, 17c, 17d, 17e, 17f, 17g.

Then, as shown in FIG. 1S, the second resist layers 26a, 26b, 26c, 26d and the second conductive layers 17a, 17g and metal layers 18a, 18g thereon are removed. In other words, the second conductive layers 17b, 17c and the metal layers 18b, 18c, which are protruded on the bottom surface of the reflection cavity 12 from the first conductive layer 11a along the electrode via hole 13a, are retained. And, the second conductive layers 17e, 17f and the metal layers 18e, 18f, which are protruded on the bottom surface of the reflection cavity 12 from the first conductive layer 11b along the electrode via hole 13b, are retained.

Subsequently, referring to FIG. 1T, a chip 19 is mounted in the reflection cavity 12 and is electrically connected to the metal layers 18b, 18f. For example, the chip 19 can be mounted on the second conductive layer 17d and the metal layer 18d that are provided on the second insulating layer 16b, and can be electrically connected to the metal layers 18b, 18f by e.g. bonding wires. Alternatively, the chip 19 can be mounted on and electrically connected to the metal layers 18c, 18e in a flip-chip manner, as shown in FIG. 1T′. In such case, the second conductive layer 17d and the metal layer 18d are removed.

Finally, an encapsulant 30 is formed in the reflection cavity 12 and the electrode via holes 13a, 13b to cover the first insulating layers, the reflection layer, the metal layers and the chip.

Further as shown in FIGS. 1T, 1T′, more specifically, the encapsulant 30 covers the exposed first insulating layers 14a, 14c, the exposed second insulating layers 16a, 16b, 16c, the exposed second conductive layers 17b, 17c, 17d, 17e, 17f, the exposed metal layers 18b, 18c, 18d, 18e, 18f and the chip 19. The encapsulant 30 also fills the electrode via holes 13a, 13b.

The LED package structure provided in the present invention, as shown in FIG. 1S, 1T or 1T′, comprises: a silicon substrate (having sections 10a, 10b, 10c) including a first surface 100, a second surface 101, a reflection cavity 12, and electrode via holes 13a, 13b penetrating through the reflection cavity 12 and the second surface 101; first conductive layers 11a, 11b formed on the second surface 101 and optionally covering the electrode via holes 13a, 13b, wherein a portion of the second surface 101 is exposed from the first conductive layers 11a, 11b; first insulating layers 14a, 14b, 14c formed on the first surface 100, surfaces of the reflection cavity 12 and surfaces of the electrode via holes 13a, 13b, wherein the first insulating layers 14a, 14b, 14c are connected to the first conductive layers 11a, 11b; metal films 15a, 15b, 15c formed on the first insulating layers 14a, 14b, 14c and in a central region and peripheral regions of the reflection cavity 12; and second insulating layers 16a, 16b, 16c formed on the metal films 15a, 15b, 15c and connected to the first insulating layers 14a, 14b, 14c.

The LED package structure further comprises: a second conductive layer 17b formed on the first insulating layer 14a and connected to the first conductive layer 11a by the electrode via hole 13a; a second conductive layer 17c formed on the first insulating layer 14b in the electrode via hole 13a and connected to the first conductive layer 11a by the electrode via hole 13a; a second conductive layer 17e formed on the first insulating layer 14b in the electrode via hole 13b and connected to the first conductive layer 11b by the electrode via hole 13b; a second conductive layer 17f formed on the first insulating layer 14c and connected to the first conductive layer 11b by the electrode via hole 13b; and a second conductive layer 17d only formed on the second insulating layer 16b.

The LED package structure further comprises: metal layers 18b, 18c formed on the second conductive layers 17b, 17c that are connected to the first conductive layer 11a by the electrode via hole 13a; and metal layers 18e, 18f formed on the second conductive layers 17e, 17f that are connected to the first conductive layer 11b by the electrode via hole 13b.

The LED package structure further comprises: a chip 19 mounted on metal layer 18d formed on the second insulating layer 16b, wherein the chip 19 is electrically connected to the metal layers 18b, 18f; and an encapsulant 30 covering the exposed first insulating layers 14a, 14c, the exposed second insulating layers 16a, 16b, 16c, the exposed second conductive layers 17b, 17c, 17d, 17e, 17f, the exposed metal layers 18b, 18c, 18e, 18f, and the chip 19, wherein the encapsulant 30 fills the electrode via holes 13a, 13b.

Compared to the conventional technology, the present invention advantageously uses a deposition technique to form conductive layers, without having to connect upper and lower conductive layers in electrode via holes, such that the conventional problems of impaired connection and poor light emitting effect do not arise and also the process complexity and cost can be reduced, thereby greatly improving the production yield. Moreover, the present invention allows the electrode via holes to be covered by the first conductive layers, such that a mold flash process does not occur during the subsequent problem of forming the encapsulant.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A light-emitting diode package structure, comprising:
a silicon substrate including a first surface, a second surface opposing to the first surface, a reflection cavity formed in the silicon substrate and communicating with the first surface, and a plurality of electrode via holes formed through a bottom surface of the reflection cavity and the second surface;
first conductive layers formed on the second surface of the silicon substrate;
first insulating layers formed on the first surface of the silicon substrate, a surface of the reflection cavity and surfaces of the electrode via holes;
a reflection layer formed on the first insulating layers located on predetermined areas of the surface of the reflection cavity;
second conductive layers formed on the surfaces of the electrode via holes and connected to the first conductive layers;
metal layers formed on the second conductive layers;
a chip mounted in the reflection cavity and electrically connected to the metal layers; and
an encapsulant formed in the reflection cavity and the electrode via holes, for covering the first insulating layers, the reflection layer, the metal layers and the chip.

2. The light-emitting diode package structure of claim 1, wherein a portion of the second surface of the silicon substrate is exposed from the first conductive layers and is located right under the chip.

3. The light-emitting diode package structure of claim 1, wherein the reflection layer comprises metal films formed on the first insulating layers, and second insulating layers covering the metal films.

4. The light-emitting diode package structure of claim 1, wherein the reflection layer is further formed on the first insulating layers located on the bottom surface of the reflection cavity.

5. The light-emitting diode package structure of claim 1, wherein the second conductive layers and the metal layers are protruded from the bottom surface of the reflection cavity.

6. A packaging method of a light-emitting diode package structure, comprising the steps of:
providing a silicon substrate having a first surface and a second surface opposing to the first surface, and forming first conductive layers on the second surface of the silicon substrate;
forming a reflection cavity from the first surface into the silicon substrate, and forming a plurality of electrode via holes penetrating through a bottom surface of the reflection cavity and the second surface of the silicon substrate;
forming first insulating layers on the first surface of the silicon substrate, a surface of the reflection cavity and surfaces of the electrode via holes;
forming a reflection layer on the first insulating layers located on predetermined areas of the surface of the reflection cavity;
forming second conductive layers on the surfaces of the electrode via holes, wherein the second conductive layers are connected to the first conductive layers;
forming metal layers on the second conductive layers;
mounting a chip in the reflection cavity, and electrically connecting the chip to the metal layers; and
forming an encapsulant in the reflection cavity and the electrode via holes, allowing the encapsulant to cover the first insulating layers, the reflection layer, the metal layers and the chip.

7. The packaging method of a light-emitting diode package structure of claim 6, wherein forming the first conductive layers comprises the steps of:
forming at least a dielectric layer on the second surface of the silicon substrate;
forming a patterned dry film on the dielectric layer on the second surface of the silicon substrate;
removing the dielectric layer uncovered by the patterned dry film so as to expose the second surface of the silicon substrate;
forming the first conductive layers on the exposed second surface of the silicon substrate; and
removing the patterned dry film and the dielectric layer covered by the patterned dry film.

8. The packaging method of a light-emitting diode package structure of claim 6, wherein forming the reflection cavity and the electrode via holes comprises the steps of:
forming at least a dielectric layer on the first surface of the silicon substrate;
forming a patterned photo resist layer on the dielectric layer on the first surface of the silicon substrate so as to expose a portion of the dielectric layer, wherein the exposed portion of the dielectric layer has a projection area beyond an area of a portion of the second surface exposed from the first conductive layers;
removing the exposed portion of the dielectric layer;
forming the reflection cavity into the silicon substrate;
removing the patterned photo resist layer and the remaining dielectric layer on the first surface of the silicon substrate;
forming first resist layers on the first surface of the silicon substrate and the surfaces of the reflection cavity, wherein the first resist layers has first resist openings for exposing portions of the bottom surface of the reflection cavity;
forming the plurality of electrode via holes from the exposed portions of the bottom surface of the reflection cavity, wherein the electrode via holes penetrate through the bottom surface of the reflection cavity and the second surface of the silicon substrate so as to expose the first conductive layers; and
removing the first resist layers.

9. The packaging method of a light-emitting diode package structure of claim 6, wherein the reflection layer comprises metal films formed on the first insulating layers, and second insulating layers covering the metal films.

10. The packaging method of a light-emitting diode package structure of claim 6, wherein the reflection layer is further formed on the first insulating layers located on the bottom surface of the reflection cavity.

11. The packaging method of a light-emitting diode package structure of claim 6, wherein forming the second conductive layers and the metal layers comprises the steps of:
forming second resist layers on the first insulating layers located on the first surface of the silicon substrate and the surface of the reflection cavity;
forming the second conductive layers on the second resist layers and the surfaces of the electrode via holes;
removing the second resist layers and the second conductive layers thereon located on peripheral areas of the electrode via holes;
forming the metal layers on the second conductive layers; and
removing the second resist layers and the second conductive layers and metal layers on the second resist layers.
